(19) United States
(12) Patent Application Publication
(10) Pub. No.: US 2010/0207631 A1
(43) Pub. Date: Aug. 19, 2010

(54) System and Method for Detecting Labeled Entities Using Microcoil Magnetic MRI

(76) Inventor: Andrew F. McDowell, Albuquerque, NM (US)

Correspondence Address: DAVIS WRIGHT TREMAINE LLP - San Francisco, 505 MONTGOMERY STREET, SUITE 800, SAN FRANCISCO, CA, 94111, US

(21) Appl. No.: 12/532,993

(22) PCT Filed: Mar. 27, 2008
(86) PCT No.: PCT/US2008/058518

§ 371 Date: Mar. 25, 2010

Related U.S. Application Data
(60) Provisional application No. 60/920,165, filed on Mar. 27, 2007.

(51) Int. Cl. G01R 33/44

(52) U.S. Cl. 324/318

(57) ABSTRACT

The present invention provides microcoil-based detectors for detection of an analyte in a fluid, and methods for their use. In particular, the detectors contain a permanent magnet (206) and a gradient magnetic field generator.

### CROSS-REFERENCE TO RELATED APPLICATIONS

The present patent application claims priority under 35 U.S.C. §119(e) to U.S. Provisional Patent Application Ser. No. 60/920,165, filed on Mar. 27, 2007, the entirety of which is herein incorporated by reference.

### FIELD OF INVENTION

The present invention relates to magnetic resonance imaging and detection of labeled molecules, cells, or other structures. Specifically, the invention relates to a method for using microcoil nuclear magnetic resonance or magnetic resonance imaging to detect labeled entities.

### BACKGROUND

Traditional nuclear magnetic resonance (NMR) detection methods involve the use of beads to label an entity such as a molecule or cell that is suspected of being present in an analyte. These beads exert an influence on a portion of the fluid surrounding the bead and can alter the signal identified by the NMR device. The signal disruption caused when a labeled entity passes through the sensitive volume of an NMR devices triggers a single detection event, and thus both false positive and false negative detections may occur, requiring multiple repetitions of any single NMR experiment to confirm a detection event, greatly decreasing at least throughput of the assay. Thus, improved detection methods are needed.

### SUMMARY

In a first aspect, the present invention provides detectors, comprising a permanent magnet possessing a field strength, wherein the field strength is less than or equal to 4 Tesla; a magnetic gradient generator capable of applying a magnetic gradient to a magnetic field generated by the permanent magnet, and a microcoil possessing an inner diameter between 25 microns and 550 microns disposed proximate to the magnetic field generated by the permanent magnet.

The detectors of the first aspect may further comprise a conduit guide capable of receiving a conduit for receiving fluid, wherein the conduit guide is capable of disposing the conduit proximate to the microcoil, proximate to the magnetic field generated by the permanent magnet, and proximate to the magnetic gradient generated by the magnetic gradient generator, and wherein the microcoil is capable of being energized at a frequency that permits detection of a magnetic resonance within a volume of fluid within the conduit. In experiments that detect a magnetic resonance within a volume of fluid within the conduit, the resonant frequency is a function of the strength of the magnetic field and the properties of the nuclei in the fluid. For example, the resonant frequencies may be less than or equal to 100 MHz.

The detectors of the first aspect may also comprise a conduit disposed proximate to the microcoil. The conduit itself may also be disposed on the conduit guide. In one variation of the detectors of the first aspect, the conduit and the microcoil may be disposed on a module, and the conduit guide may be capable of receiving the module.

The detectors of the first aspect may further comprise a signal processor capable of being electrically coupled to the microcoil and capable of identifying a plurality of frequency components and a plurality of magnitude components within a signal received from the microcoil, and capable of correlating the plurality of magnitude components and plurality of frequency components to a presence or absence of an entity in a volume of fluid at a plurality of locations along an axial length of the conduit.

The detectors of the first aspect may further comprise a fluidic drive capable of being fluidically coupled to the conduit.

The detectors of the first aspect may further comprise a tuning circuit electrically coupled to the microcoil. The tuning circuit comprises a tuning coil capable of having an inductance at least two times larger than the inductance of the microcoil. The tuning circuit also comprises a capacitor coupled to the tuning coil to form a resonant circuit.

For detectors of the first aspect that comprise a conduit, the conduit may comprise a plurality of branches capable of receiving a volume of fluid. Further, the plurality of branches may be disposed proximate to a plurality of microcoils, wherein each microcoil within the plurality of microcoils possesses an inner diameter between 25 microns and 550 microns.

In a second aspect, the present invention provides detectors comprising a permanent magnet possessing a field strength, wherein the field strength is less than or equal to 4 Tesla, a magnetic gradient generator capable of applying a magnetic gradient to a magnetic field generated by the permanent magnet, and a conduit guide capable of receiving a conduit for receiving fluid and a microcoil capable of being energized at a frequency that permits detection of a magnetic resonance within a volume of fluid within the conduit. The conduit guide is capable of disposing a microcoil proximate (i) the magnetic field generated by the permanent magnet and (ii) the magnetic gradient, and the conduit guide is also capable of disposing a conduit proximate to the microcoil.

The detectors of the second aspect may also comprise a tuning circuit capable of being coupled to the microcoil. The tuning circuit comprises a tuning coil that possesses an inductance of at least 2 nH, and the tuning coil is coupled to a capacitor to form a resonant circuit.

The detectors of the second aspect may further comprise a microcoil disposed on the conduit guide, wherein the microcoil is disposed proximate to the magnetic field generated by the permanent magnet, is capable of being energized at a frequency that permits detection of a magnetic resonance within a volume of fluid, and is electrically coupled to the tuning circuit. The microcoil may possess an inner diameter between 25 microns and 550 microns.

The detectors of the second aspect may further comprise a conduit disposed on the conduit guide, wherein the conduit is disposed proximate to the microcoil and is capable of receiving a volume of fluid. A fluidic drive may also be fluidically coupled to the conduit. Both the microcoil and the conduit may be disposed on a removable module, wherein the removable module is disposed on the conduit guide.

The conduit itself may further comprise a plurality of branches capable of receiving a volume of fluid. The plurality of branches may be disposed proximate to a plurality of microcoils, wherein each microcoil within the plurality of microcoils possesses an inner diameter of between 25 microns and 550 microns.

The detectors of the second aspect may further comprise a signal processor capable of being electrically coupled to the microcoil. The signal processor is also capable of identifying a plurality of frequency components and a plurality of magnitude components within the signal received from the microcoil. The signal processor is also capable of correlating the plurality of frequency components and the plurality of magnitude components to the presence or absence of an entity in the volume of fluid at a plurality of locations along an axial length of the conduit.

In a third aspect, the present invention provides methods for detecting a labeled entity in a flowing fluid comprising

(a) applying a magnetic gradient to a magnetic field, wherein a conduit containing a flowing fluid is disposed in the magnetic field and within the magnetic gradient, and wherein a microcoil is disposed proximate to the conduit;

(b) energizing the microcoil at a frequency that permits detection a magnetic resonance within the flowing fluid: and

(c) processing a signal received from the microcoil to detect a labeled entity in the flowing fluid, wherein the processing comprises:

identifying a plurality of frequency components and a plurality of magnitude components within the signal received from the microcoil and correlating the plurality of frequency components and the plurality of magnitude components to a presence or absence of a labeled entity in the flowing fluid at a plurality of locations along the axial length of the conduit.

The methods may further comprise processing a plurality of signals from different time points.

The methods of this aspect may be applied to flowing fluids that flow through the conduit at a rate between 0.01 microliters per minute and 500 microliters per minute.

The methods of this aspect may further comprise electrically coupling the microcoil to a tuning circuit, wherein the tuning circuit comprises a tuning coil having an inductance at least two times the inductance of the microcoil and a capacitor coupled to the tuning coil to form a resonant circuit.

The methods of this aspect may further comprise generating a graphic representation depicting the plurality of frequency components and the plurality of magnitude components. The processing may further comprise performing a Fourier transformation on the signal received from the microcoil.

Any of the methods of this aspect of the present invention may be implemented by a computer program, and may be carried out using any of the detectors according to any aspect and embodiment of the present invention.

In a fourth aspect, the present invention provides modules comprising
a microcoil, wherein the microcoil possesses an inner diameter between 25 microns and 550 microns;
a conduit disposed proximate to the microcoil; and
a connector for connecting the module to a detector.

The module may further comprise electrical contacts within the housing capable of establishing an electrical connection between the module and a magnetic resonance signal processor or other electrical components within a detector, such as those disclosed herein. The module may further comprise a fluidic drive within the housing fluidically coupled to the conduit. Other fluidic components that may be fluidically coupled to the conduit, such as valves, sequestration chambers, and affinity columns may also be included in the module.

In a further aspect, the present invention provides computer readable storage media, for automatically carrying out the methods of the invention on a detector.

These and other aspects, objectives, and advantages of the invention will become further apparent to those of ordinary skill in the art by reading the following detailed description, with reference where appropriate to the included figures.

### BRIEF DESCRIPTION OF THE FIGURES

FIG. 1 depicts a portion of a detector in accordance with an embodiment of the present invention.

FIG. 2 depicts a cross-sectional view of a detector in accordance with an embodiment of the present invention.

FIG. 3 depicts three example microcoil constructions.

FIG. 4 depicts a portion of a detector comprising a conduit that contains multiple conduit branches.

FIG. 5 depicts a portion of a detector comprising additional fluidic components coupled to a conduit.

FIG. 6 depicts a portion of a detector comprising three affinity columns arranged to permit multiplexing of a fluid sample.

FIGS. 7a-7c depict schematic diagrams of electrical connections between a tuning circuit and a microcoil.

FIG. 8 depicts an example module.

FIG. 9 is a time series of images generated in accordance with a method of the present invention.

FIG. 10 is a contour plot depicting the full time course of a detection experiment conducted in accordance with a method of the present invention.

FIG. 11 is a graphical representation of the movement of an entity through a conduit developed in accordance with a method of the present invention.

### DETAILED DESCRIPTION OF EXEMPLARY EMBODIMENTS

In a first aspect, the present invention provides detectors comprising

(a) a permanent magnet possessing a field strength, wherein the field strength is less than or equal to 4 Tesla;

(b) a magnetic gradient generator capable of applying a magnetic gradient to a magnetic field generated by the permanent magnet; and

(c) a microcoil disposed proximate to the magnetic field generated by the permanent magnet, wherein the microcoil possesses an inner diameter of between 25 microns and 550 microns.

The detectors of the present invention can be used, for example, in magnetic resonance imaging (MRI) detection methods. One benefit of the detectors and methods of the invention is a decreased susceptibility to false positive and false negative detections by examining a multiplicity of sections of a microcoil during a single detection experiment and providing a graphical representation of the test data. Further, the use of permanent magnets with field strengths less than or equal to 4 Tesla permits the detectors to be constructed into small, portable units that can be easily carried and moved. Further, where other miniaturized imaging platforms analyze static entities in static samples, the detectors and methods of the present invention permit the analysis of flowing fluids, thus facilitating more rapid analyses of larger sample sizes.

The detectors of this first aspect of the invention comprise a permanent magnet. The permanent magnet possesses a field strength, wherein the field strength is less than or equal to 4 Tesla. In various embodiments, the field strength may be between 0.1-4, 0.1-3.8, 0.1-3.6, 0.1-3.4, 0.1-3.2, 0.1-3.0, 0.1-2.8, 0.1-2.6, 0.1-2.4, 0.1-2.2, 0.1-2, 0.1-1.9, 0.1-1.8, 0.1-1.7, 0.1-1.6, 0.1-1.5, 0.1-1.4, 0.1-1.3, 0.1-1.2, 0.1-1.1, 0.1-1.0, 0.25-4.0, 0.25-3.5, 0.25-3.0, 0.25-2.5, 0.25-2, 0.25-1.9, 0.25-1.8, 0.25-1.7, 0.25-1.6, 0.25-1.5, 0.25-1.4, 0.25-1.3, 0.25-1.2, 0.25-1.1, 0.25-1.0, 0.5-2, 0.5-1.9, 0.5-1.8, 0.5-1.7, 0.5-1.6, 0.5-1.5, 0.5-1.4, 0.5-1.3, 0.5-1.2, 0.5-1.1, and 0.5-1.0 Tesla. The permanent magnet may be constructed out of a single magnet, or a plurality of permanent magnets may be combined. Further, any materials used in the construction of permanent magnets may be used to form the permanent magnet for the detector. For example, iron, other ferrous and non-ferrous alloys, and ceramic magnetic materials including SmCo and NdFeB and other magnetic materials may be used. The permanent magnet may also be formed into any shape. For example, magnets (or combinations of magnets) with curved, rectangular, cylindrical, or other profiles may be used. In an example detector, a dipole magnet with steel pole pieces is used as the permanent magnet. However, other magnets, such as Halbach magnets may also be used. In an example detector, the magnetic field produced by the permanent magnet is uniform. However, permanent magnets that form magnetic fields possessing gradients, such as the static gradients sometimes encountered when constructing magnets, may also be used in the detector. The slope of the gradient that may be present from the permanent magnet may range between 0 G/cm and 1.0 G/cm. In embodiments where the permanent magnet possesses a gradient, the gradient generated by the magnetic gradient generator differs in strength of type (for example, pulsed vs. static). The detector may also comprise a multiplicity of permanent magnets with a multiplicity of magnetic fields. In an example detector, two permanent magnets may be used, the first with a magnetic field strength of 2.0 Tesla, and the second with a magnetic field strength of 1.0 Tesla. The use of different magnetic field strengths during the course of a detection experiment may facilitate the detection of a variety of different entities with a fluid sample. Further, since the resonant frequency of the nuclei in a fluid varies with the field strength, the use of detectors with a multiplicity of field strengths may further reduce the likelihood of false positive or false negative detections by analyzing a fluid at more than one field strength and frequency.

The detectors of this first aspect of the invention comprise a magnetic gradient generator. The gradient is used to differentiate between a plurality of signal detection volumes within a microcoil. The gradient may also be used to compensate for a gradient in the magnetic field generated by the permanent magnet. Any magnetic gradient generator capable of applying a magnetic gradient to the magnetic field generated by the permanent magnet may be used, including but not limited to permanent magnets, superconducting electromagnets, or gradient coils. In an example detector, the magnetic gradient is linear, though any gradient may be used, including, but not limited to non-linear gradients. The gradient generator may generate gradients with slopes between 0.01 G/cm and 1.0 G/cm. In various embodiments, the slope of a localized area of the gradient generated by the magnetic gradient generator is between 0.01-1.0, 0.015-1.0, 0.02-1.0, 0.02-0.9, 0.02-0.8 0.02-0.7, 0.02-0.65, and 0.02-0.6 G/cm. As discussed above, in embodiments where the permanent magnet possesses a gradient, the gradient generated by the magnetic gradient generator differs in strength of type (for example, pulsed vs. static) A static gradient is used in an example detector because static gradients are particularly compatible with miniaturized NMR and MRI platforms, and are relatively simple compared to other gradients. However, other gradient types may be used, including but not limited to pulsed gradients and combinations of pulsed and static gradients. The strength of the gradient used in a detector determines the spatial resolution of the detector. Increasing the strength of the magnetic gradient permits the detector to identify magnetic resonances in smaller sections of the microcoil. In an example detector, a magnetic gradient of 0.07 G/mm is used in conjunction with a microcoil that is 1.1 mm in length. Using the weakest gradient that still provides the desired spatial resolution may facilitate more narrow detection bandwidths and improved signal-to-noise characteristics of the detector. In an example detector, a magnetic gradient is selected based on the T₂* of the sample fluid, without changing the center frequency of the energy emitted by the sample fluid during a detection experiment is used. In an example detector, a first magnetic gradient of approximately 0.14 G/mm may be applied during a first analysis of a sample. If the results of the analysis are inconclusive, or if improved signal-to-noise characteristics are desired, a second gradient of 0.07 G/mm may be applied during a second analysis of the same sample.

The detectors of this first aspect of the invention comprise a microcoil disposed proximate to the magnetic field generated by the permanent magnet, wherein the microcoil possesses an inner diameter between 25 microns and 550 microns. In various embodiments, the inner diameter of the microcoil can be between 25-500, 25-450, 25-400, 25-350, 25-300, 25-250, 25-200; 50-550, 50-500, 50-450, 50-400, 50-350, 50-300, 50-250, 50-200, 100-550, 100-500, 100-450, 100-400, 100-350, 100-300, 100-250, and 100-200 microns. In an example detector, the microcoil is solenoidal in shape and can be wound around a section of a conduit that holds the volume of fluid during a detection experiment. However, other coil shapes may be used, including but not limited to planar coils, rectangular coils, saddle coils, and meanderline coils. For example, a flat or a solenoidal microcoil may be capable of being oriented perpendicularly to the axis of a conduit, and the coil may be filled with a material, for example but not limited to, ferrites, to enhance the sensitivity of the coil. Further, the microcoil may be formed through other construction techniques, including but not limited to depositing the coil material on a surface or etching the coil. The length of the microcoil can be selected such that the length of the microcoil is coextensive with the uniform region of the magnetic field generated by the permanent magnet. Other lengths may also be selected. In various embodiments, the length of the microcoil is between 25 μm-5 cm, 50 μm-5 cm, 75 μm-5 cm, 100 μm-5 cm, 100 μm-4 cm, 100 μm-3 cm, 100 μm-2 cm, 100 μm-1.5 cm, 100 μm-1 cm, 1.5 mm-1.5 cm, 2.0 mm-1.5 cm, 3 mm-1.5 cm, 4 mm-1.5 cm, 5 mm-1.5, 6 mm-1.5 cm, 7 mm-2 cm, 8 mm-1.5 cm, and 9 mm-1 cm. In an example detector, the microcoil is 1.1 mm. Generally, the strength of the signal produced by a microcoil increases with the length of the coil. Some detectors may include a multiplicity of differently-sized microcoils. In an example detector, a first microcoil with a larger inner diameter is used to conduct an initial analysis of a sample. If the presence of an entity in a fluid is detected by the first microcoil, the fluid may be diverted to be analyzed at a higher sensitivity by a second microcoil with a smaller inner diameter.

As used herein, the microcoil being “disposed proximate to the magnetic field” means that at least a portion of the microcoil is located within the magnetic field produced by the permanent magnet. In an example detector, the entire coiled section of a solenoidal microcoil is placed within a magnetic field and oriented such that the magnetic field observed at all points on the coiled section of the solenoidal microcoil is uniform. However, any orientation of the microcoil within the magnetic field may be used, provided that the orientation also aligns the microcoil with a non-zero component of the magnetic gradient. For example, the microcoil may be angled with respect to the direction of the magnetic field, and portions of the microcoil, such as the ends or the electrical leads from the microcoil, may extend beyond the magnetic field.

As used herein, the microcoil being “disposed proximate to the magnetic gradient” means that at least a portion of the microcoil is placed within the magnetic gradient generated by the magnetic gradient generator. In an example detector, the microcoil is located within the magnetic gradient and oriented such that the axis of the microcoil is aligned to be parallel to the direction of a linear magnetic gradient. However, any orientation of the microcoil with respect to the gradient that aligns the microcoil with a non-zero component of the magnetic gradient may be used. As will be understood by those of skill in the art based on the teachings herein, disposition of the microcoil proximate to the gradient and proximate to the magnetic field are separate variables in design of the detectors of the invention.

The detectors of this first aspect may further comprise a conduit guide capable of receiving a conduit for receiving fluid, wherein the conduit guide is capable of disposing the conduit proximate to the microcoil and proximate to the magnetic field generated by the permanent magnet (and proximate to the magnetic gradient when the detector is in use), and wherein the microcoil is capable of being energized at a frequency that permits detection of a magnetic resonance within a volume of fluid within the conduit based on the strength of the magnetic field generated by the permanent magnet. The frequency that permits detection of a magnetic resonance within a volume of fluid varies with the strength of the magnetic field such that f=γ′B, where f is the frequency, B is the magnetic field strength, and γ′ is a proportionality constant based on the nuclei examined within the fluid. For example, γ′ for the nuclei of hydrogen atoms is approximately 42.6 MHz/Tesla. In various examples, the frequency that permits detection of a magnetic resonance with in a volume of fluid in the conduit is between 1-100, 10-100, 20-100, 30-100, 40-100, 50-100, 60-100, 70-100, 80-100, 90-100, 20-85, 30-85, 40-85, 50-85, 60-85, 70-85, 80-85, 20-65, 30-65, 40-65, 60-65, and 35-45 MHz.

The conduit guide may comprise any means for orienting the conduit, including but not limited to mounting brackets, mechanical guides, and couplings. The conduit guide can be made from any material or materials that are capable of establishing and maintaining the position of the conduit guide. For example, metals, plastics, composite materials, ceramics, and multi-layer materials can be used individually or in combination to form the conduit guide. In an example detector, the conduit guide also aligns the axis of the portion of the conduit that holds the sample fluid (sensitive volume) during an experiment with the direction of the magnetic gradient produced by the magnetic gradient generator. In another example detector, the conduit guide is adjustable to permit an operator to select a position of the conduit relative to the magnetic gradient that minimizes a frequency shift in a signal emitted by the sensitive volume when the magnetic gradient is energized. In embodiments that utilize a coil as a magnetic gradient generator, the conduit guide may align the long axis of a cylindrical conduit with the center of the gradient coil. However, the conduit guide may dispose the conduit in other positions and orientations as deemed appropriate by an operator.

The detectors of the first aspect may further comprise a signal processor electrically coupled to the microcoil and capable of identifying a plurality of frequency components and a plurality of magnitude components within the signal received from the microcoil, and capable of correlating the plurality of magnitude components and plurality of frequency components to a presence or absence of an entity in a volume of fluid at a plurality of locations along an axial length of the conduit. The signal processor may use any method for identifying frequency components and magnitude components within a signal. In an example detector, the signal processor is capable of performing a fast Fourier transformation on the signal received from the microcoil to identify a plurality of frequency components and a plurality of magnitude components within the signal from the microcoil. The signal processor may comprise the computer programs disclosed herein.

The detectors of the first aspect of the invention may also comprise a conduit disposed on the conduit guide and proximate to the microcoil. Any conduit capable of receiving a fluid sample may be used, including but not limited to a capillary tube. In an example detector, the conduit is hollow and cylindrical in shape, with the inner and outer diameters sized to accommodate picoliter-microliter volumes within the sensitive volume of the detector. The inner diameter of the conduit may be selected based on the properties of the fluid used in a detection experiment, as well as other parameters of a detection experiment such as the strength of the signal produced by a fluid, the flow rate of the fluid, and the desired resolution of the experiment, for example. The conduit has an inner diameter between 25 and 550 microns. In various embodiments, the conduit inner diameter can be between 25-500, 25-450, 25-400, 25-350, 25-300, 25-250, 25-200; 50-550, 50-500, 50-450, 50-400, 50-350, 50-300, 50-250, 50-200, 100-550, 100-500, 100-450, 100-400, 100-350, 100-300, 100-250, and 100-200 microns. The outer diameters can be any that may suitably be used with conduits of the inner diameters disclosed herein. Further, in example detectors where the microcoil is used to retain the fluid, the wall thickness of the conduit may be reduced to zero. The efficiency of the detector may be improved by reducing the difference between the inner and outer diameters of the conduit. An example conduit is a capillary tube with an inner diameter of 100 microns and an outer diameter of 170 microns. Conduits conforming to different shapes may also be used, including but not limited to elliptical conduits. Further, the conduit may comprise multiple sections, and may include removable sections. Removable sections, for example, may facilitate a reduction in the probability of a contamination of a sample or may permit the device to be more readily cleaned or repaired. The conduit itself may be disposed on the conduit guide, either directly placed thereon or indirectly with another component serving to guide the conduit into the conduit guide. In one embodiment, the conduit is disposed on a module, discussed in more detail below, that the conduit guide is capable of receiving.

The conduit can receive fluid from any suitable component, including but not limited to a reservoir for providing fluid to the conduit. Such a reservoir can be on board the device or on the module discussed above. The reservoir can simply be a component of the conduit in which a valve is placed to control flow from the reservoir to the portion of the conduit used for analysis.

As used herein, the conduit being “disposed proximate to the microcoil” means any position from which a signal transmitted from the microcoil can reach the conduit and the corresponding energy released from the fluid in the sensitive volume of the conduit can induce an electrical current in the microcoil. In an example embodiment, a solenoidal microcoil is wrapped around the conduit, such that the axis of the microcoil is parallel with the axis of the conduit. In another example, a planar coil is located immediately adjacent to the conduit and oriented such that the center axis of the planar coil is perpendicular with the center axis of the conduit.

Further, the conduit may comprise a plurality (i.e.: two or more) of branches capable of receiving a volume of fluid. The plurality of branches may be disposed proximate to a plurality of microcoils, wherein each microcoil is as described above. In one embodiment, each branch is disposed proximate to a separate microcoil, where each branch and each microcoil may be the same or have different sizes as deemed appropriate for the specific use. For example, the plurality of branches may permit the division of a fluid sample into multiple subsamples, or may permit assaying of more than one fluid sample at a time. In a further embodiment, one or more branches of the conduit are used in other fluidic processes. For example, one or more branches may be fluidically coupled to one or more affinity columns. In experiments that use labeling beads to aide in the identification of entities in a fluid, different labels may be added to each of the subsamples. The plurality of branches may also be coupled to valves, sequestration chambers, and/or other fluidic structures as suitable for a given purpose. Such fluidic components can be “on board” the detector, or may be provided via a removable module, such as one that can be connected to the conduit guide.

In embodiments with multiple branches and multiple microcoils, various methods may be used to identify the magnetic resonance behaviors within a given microcoil. For example, the microcoils may be angled with respect to the magnetic gradient such that each spatial element of each microcoil resonates at a different range of frequencies. In another example, electrical switching could be used to selectively monitor a microcoil for a period of time. In another example, each microcoil may be coupled to a dedicated signal processor.

The detectors of the first aspect may further comprise a fluidic drive, capable of being fluidically coupled to the conduit. The fluidic drive may permit the purposeful diving of a fluid in the conduit. Typically, the fluidic drive operates by applying a change in the pressure on one end of the conduit. For example, a vacuum may be attached to one end of the conduit to draw the fluid through a portion of the conduit. A positive displacement pump, such as a syringe pump may also be used to establish fluid flow. The fluid drive may also use air pressure or gravity to drive the fluid. Any device that is capable of imparting a flow to a fluid in the conduit may be used. The fluidic drive can be “on board” the detector, or may be provided via a removable module, such as one that can be connected to the conduit guide (described in more detail below).

The detectors of the first aspect may further comprise a tuning circuit electrically coupled to the microcoil. The tuning circuit comprises a tuning coil capable of having an inductance at least two times larger than the inductance of the microcoil, and a capacitor coupled to the tuning coil to form a resonant circuit. In various embodiments, the tuning coil may have an inductance that is 3, 4, 5, 6, 7, 8, 9, 10, 20, 25, 50, 100, 250, 500, or 1000 times larger than the inductance of the microcoil. The tuning coil may be coupled to the microcoil to form a series or a parallel connection with the microcoil. Any method of coupling the microcoil to the tuning coil may be used, including but not limited to a transmission line between the microcoil and the tuning coil. An example tuning circuit is disclosed in U.S. Patent Application Publication 2008-0042650, “Tuning Low-Inductance Coils at Low Frequencies,”, incorporated herein by reference. Such tuning coils can be “on board” the detector, may be provided via a removable module, such as one that can be connected to the conduit guide, or a combination thereof.

In a second aspect, the present invention provides detectors comprising

(a) a permanent magnet possessing a field strength, wherein the field strength is less than or equal to 4 Tesla;

(b) a magnetic gradient generator capable of applying a magnetic gradient to a magnetic field generated by the permanent magnet; and

(c) a conduit guide capable of receiving a (i) conduit for receiving a fluid, and (ii) a microcoil capable of being energized at a frequency that permits detection of a magnetic resonance within a volume of fluid within the conduit; wherein the conduit guide is capable of disposing the microcoil proximate to (i) the magnetic field generated by the permanent magnet and (ii) the magnetic gradient, and

wherein the conduit guide is capable of disposing the conduit proximate to the microcoil

All embodiments and combinations of permanent magnets, magnetic gradient generators, and conduit guides disclosed above for the first aspect of the invention are also suitable for the detectors of this second aspect of the invention.

The detectors of the second aspect may also comprise a signal processor capable of being electrically coupled to the microcoil. All embodiments of signal processors disclosed above for the first aspect of the invention are also suitable for the detectors of this second aspect of the invention.

In one embodiment of this second aspect, the detector further comprises a microcoil disposed on the conduit guide, wherein the microcoil is (i) disposed proximate to the magnetic field generated by the permanent magnet (and proximate to the magnetic field when the detector is in use), (ii) capable of being energized at a frequency that permits detection of a magnetic resonance within a volume of fluid, and (iii) electrically coupled to the tuning circuit. All embodiments of microcoils disclosed above for the first aspect of the invention are also suitable for the detectors of this second aspect of the invention.

In another embodiment of this second aspect, the detector further comprises a conduit disposed on the conduit guide, wherein the conduit is (i) disposed proximate to the microcoil and (ii) capable of receiving a volume of fluid. All embodiments of conduits disclosed above for the first aspect of the invention are also suitable for the detectors of this second aspect of the invention.

The detectors of the second aspect may also comprise a tuning circuit capable of being coupled to a microcoil. The tuning circuit comprises a tuning coil that possesses an inductance of at least 2 nH, and the tuning coil is coupled to a capacitor to form a resonant circuit. In various embodiments, the inductor may have an inductance between 2 nH-1 μH, 10 nH-1 μH, 50 nH-1 μH, 100 nH-1 μH, 200 nH-1 μH and 500 nH-1 μH. The tuning circuit in the second aspect may be configured and coupled to the microcoil in any of the configurations used in the first embodiment. Any tuning coil with an inductance of at least 2 nH and a radio-frequency resistance less than the radio-frequency resistance of the microcoil may be used. In both the first and second aspects of the detector aspect of the present invention, tuning coils with larger inductances may facilitate easier tuning of the tuning circuit at frequencies below 100 MHz, especially when using smaller microcoils. Such tuning coils can be “on board” the detector, may be provided via a removable module, such as one that can be connected to the conduit guide, or a combination thereof. All embodiments and combinations of the tuning coils of the first aspect can be used in this second aspect of the invention.

The present invention also provides modules that can be used with various embodiments of the detectors of the first and second aspects of the invention, wherein the modules comprise:
a microcoil, wherein the microcoil possesses an inner diameter between 25 microns and 550 microns;
a conduit disposed proximate to the microcoil; and
a connector for connecting the module to a detector.

The modules of the invention can be used, for example, to couple disposable components of the detectors of the invention to permanent portions by connecting the module to the detector via, for example, the conduit guide as discussed above. For example, the module may permit all or part of the fluid used in a detection experiment to be contained on the removable module, thus reducing the probability that portions of a fluid sample will leak into the detector. The use of multiple modules may also reduce the probability of contamination between detection experiments because each fluid sample could be assigned its own module that had not come in contact with other fluid samples. Removable modules also permit the conduit and microcoil characteristics to be adjusted based on the fluid used, or other aspects of a detection experiment. For example, a longer microcoil may be used in one experiment. In another example, a larger-diameter conduit may be used.

The module comprises a connector for connecting the module to a detector, such as those disclosed above. In one embodiment, the detector further comprises a module ID reader.

The microcoil and conduit can be any embodiment disclosed above for the first and second aspects of the invention, including embodiments employing a plurality of conduit branches and/or microcoils.

To provide structural support or make the module easier to handle, the module may be disposed on a surface, such as a card or board for example, or the removable module may be disposed in a housing. However, no support or housing means are necessary. For example, the module may comprise a section of a conduit with a solenoidal microcoil wrapped around a portion of the conduit.

Any connector capable of coupling the module to a detector may be used. For example, any of the conduit guides described as part of the detector or method aspects of the present invention may be used. Further, any mechanical coupling capable of securing the module in place may be used. For example, a connector where threaded screws or bolts on the module were coupled to corresponding threaded holes on the detector may be used. Other example connectors include mechanical clips, snap fittings, mortise-and-tenon connections, pins, socket fittings, and compression fittings.

The module may further comprise electrical contacts capable of establishing an electrical connection between the microcoil or the module and the detector. The electrical connection between the removable module and the detector may permit the microcoil to interface with a tuning circuit, signal processor, or any other circuitry on a detector, such as those disclosed herein. In removable modules that contain electronics such as signal generators, signal processors, tuning circuits and other electronics on the removable module, the electrical connection between the removable module and the detector may permit any of the electronic components on the removable module to interface with electrical components within the detector. For example, the electrical connection could be used to supply power to the removable module or allow the removable module to connect to a user interface. Any means of establishing an electrical connection may be used. For example, wire leads coupled to the microcoil may extend from the module. In embodiments where the microcoil is electrically connected to the module, conductive traces may establish a connection between the microcoil and an electrical coupling on the module, which may be inserted into a receptacle on a detector.

The module may further comprise a fluidic drive fluidically coupled to the conduit. Any of the fluidic drives disclosed above may be used with the module. Other fluidic components that may be fluidically coupled to the conduit, such as valves, sequestration chambers, and affinity columns may also be included on the removable module.

Any valve that is capable of being fluidically coupled to a portion of the conduit may be used with the modules of the invention. A valve may allow the flow of a fluid in the conduit to be controlled. For example, in modules with conduits that contain a plurality of branches, one or more valves may be used to sequence the flow of a fluid through the plurality of branches. A sequestration chamber (which may be, for example, a well on a microplate, a separate conduit branch, a reservoir, etc.) may be used to hold a portion of a fluid used in a detection experiment. For example, a valve may be used to divert a portion of the fluid into a sequestration chamber if an entity is detected in the fluid. Any volume sequestration chamber may be used. For example, a small volume of a few nanoliters may be enough to allow for a subsequent microscopic evaluation of the fluid in which analyte is detected. In another example, several microliters, or even the entire volume of a sample fluid may be held in the sequestration chamber.

An affinity column may be used with the modules of the invention to trap a target entity and permit the target entity to be labeled with a labeling bead. For example, one or more affinity columns may be used with a substance that potentially contains a target entity to immobilize the target entity as a way to concentrate the fluid prior to flowing the fluid through a detection zone of the conduit.

In an example detector, the module can slide into the detector on conduit guides that place the conduit and the microcoil in a uniform region the field generated by the permanent magnet. The microcoil can be mounted directly on the conduit, and electrical leads extending from the microcoil can extend to electrical contact pads or connector on an edge of the module. Any other fluidic channels that are used in the course of the detection experiment can also be contained on the module. The conduit guides also place the module in a selected alignment with the magnetic gradient coil and a vacuum fluidic drive.

In a further aspect, the present invention provides methods for detecting a labeled entity in a flowing fluid, comprising:

applying a magnetic gradient to a magnetic field, wherein a conduit containing a flowing fluid is disposed in the magnetic field and within the magnetic gradient, and wherein a microcoil is disposed proximate to the conduit;

energizing the microcoil at a frequency that permits detection of a magnetic resonance within the flowing fluid; and processing a signal received from the microcoil to detect a labeled entity in the flowing fluid, wherein the processing comprises:
identifying a plurality of frequency components and a plurality of magnitude components within the signal received from the microcoil, and correlating the plurality of magnitude components and plurality of frequency components to a presence or absence of a labeled entity in the flowing fluid at a plurality of locations along an axial length of the microcoil.

In one embodiment, the processing comprises processing a plurality of signals received from the microcoil over time (ie: two or more time points), wherein the processing comprises identifying a plurality of frequency components and a plurality of magnitude components within each signal received from the microcoil, and correlating the plurality of magnitude components and plurality of frequency components within each signal to a presence or absence of a labeled entity in the flowing fluid at a plurality of locations along an axial length of the microcoil. In this embodiment, signals are processed from two or more time points (i.e.: 2, 3, 4, 5, 6, 7, 8, 9, 10, or more), permitting correlation of signal data from two or more different time points to identify an appropriate correlation between signals, confirming that the signal is not caused by background or other electrical disturbances. For example, a first signal is detected in one location and a second signal is detected at a second time point at an appropriate distance from the first signal, based on fluid velocity and other factors. Those of skill in the art will understand, based on the teachings herein, that appropriate spacing between time points will depend on a variety of factors, including but not limited to microcoil size, fluid velocity and viscosity, conduit size, etc.

The methods of the present invention can be used, for example, in MRI detection of one or more labeled molecules (“entity”) in a fluid; the methods disclosed herein provide dramatic reduction in susceptibility to false positive and false negative detections. The methods permit the detection of a labeled entity in a flowing fluid, and also permit multiplexing of the detection process, providing the reliability of repeated single NMR experiments in a single experiment. The methods also permit the presence and movement of a labeled entity within a sample volume to be observed and recorded. Entities that can be detected using the devices and methods of the invention, include, but are not limited to, cells (such as bacteria, fungi, other parasites, cancer cells, etc.), viruses, proteins (including antibodies), prions, nucleic acids, carbohydrates, lipids, small molecules, antibiotics, toxins, etc.

In various embodiments, detection via the methods of the invention can comprise detection, identification, and/or quantitation of entities in a sample fluid. Any sample fluid of interest can be used, including but not limited to bodily fluid samples (blood, urine, saliva, semen, vaginal secretions, tears, amniotic fluid, cerebral spinal fluid, etc.), swab samples from skin, wound, or other body sites; semi-solid samples, such as fecal samples (processed by appropriate sample dilution in a liquid), environmental water, industrial wastes, process water, liquid foodstuffs (including but not limited to milk, juice, drinking water, soda, etc.) or water used to wash foodstuffs such as vegetables and fruit. The size of the sample volume may vary depending on the properties of the fluid being analyzed, the desired flow rate through the sensitive volume, and the sizes of the conduit. The sensitive volume of the conduit (i.e.: the volume being analyzed) can vary depending on the size of the sample volume, the size of the conduit, the flow rate, the size of the microcoil, and other factors as determined by a user. In various embodiments, the sensitive volume ranges between 100 picoliters and 50 microliters. In various other embodiments, the sensitive volume is ranges between 4-7, 2-10, 1-15, 0.5-20, 0.4-50, 0.3-75, 0.2-100, 0.1-150, 0.05-300, 0.04-500, 0.03-1000, 0.02-2000, 0.01-5000 nanoliters. In an example detector, less than a nanoliter of fluid is contained in the sensitive volume of the detector at any given time. However, nanoliter, microliter, and even milliliter-sized samples may be used depending on the overall capacity of the detector. For larger samples, or samples suspected of having low concentrations of targeted entities, the use of a concentrating mechanism such as an affinity column may facilitate a reduction in the sample volume. For example, an environmental sample of 50 milliliters may be suspected of containing low concentrations of a target entity. To speed up the detection process, an affinity column with a moiety capable of selectively binding to the target entity may be used to isolate and hold the target entity while the remainder of the sample is washed away. After the extraneous portion of the sample is removed, and carrier fluid can be passed through the affinity column to carry the previously trapped target entities into the sensitive volume of the detector.

Any suitable method for labeling target entities can be employed. In various embodiments of the methods of the invention can comprise labeling a target entity with a detection enhancing label using specific attachment chemistry to influence the magnetic resonance properties of the sample fluid. Any label that can be used to specifically target an entity of interest can be used, including but not limited to magnetic beads derivatized for binding to an entity of interest. In an example use of a label, a magnetic bead labels a pathogen by using antibodies bound to the magnetic bead that are selective for target antigens on the pathogen. The magnetic bead alters the magnetic resonance of the fluid surrounding the bead, causing the fluid surround the bead to behave differently than the fluid would in the absence of the magnetic bead. Any bead that causes the target entity or the fluid surrounding the target entity to exhibit different magnetic resonant behavior than the remaining fluid in a sample can be used as a label. For example, magnetic and non-magnetic beads can be used. In another example use of a label, a plurality of different beads with known magnetic resonance profiles and the ability to attach to specific target entities are added to a fluid sample. If one of the known magnetic resonance profiles is detected during an experiment, then the corresponding entity is present within the fluid. By using a multiplicity of different beads during a single experiment, a single experiment can be used to detect a multiplicity of entities within the fluid.

The label may also be one that modifies signal by displacement of the medium surrounding the object(s), such as through attachment of glass or plastic beads. Alternatively a label may be used that enhances or changes the signal, such as by attachment of a material whose properties are measured directly, as opposed to the signal from the medium. For example, the bead could consist of iron, iron oxide (Fe₂O₃, Fe₃O₄), gadolinium metal or gadolinium oxide, iron nitride (Fe₄N), or other ferromagnetic, paramagnetic, or super-paramagnetic material encapsulated in some manner, for example, encapsulated in glass or in a plastic. The bead could also be made up almost entirely of the magnetic material, either coated or uncoated. A coating might be applied to guarantee inertness in the fluid of interest, to stabilize the magnetic particle against degradation during use or storage, or to allow the attachment of other materials or coatings in order to optimize some behavior, such as attachment of antibodies for the facilitation of attaching to the target entity.

Magnetic material may be chosen to provide the best possible magnetic moment, or provide the best overall signal performance. As some materials saturate in an applied field, another material with a lower magnetic moment might allow for a better overall signal due to lack of saturation. The magnetic material could be ferro-magnetic, ferri-magnetic, para-magnetic, super-paramagnetic, or diamagnetic. If ferro-magnetic, the beads may be magnetized prior to their use in the device, or they may be demagnetized initially and become permanently magnetized as they pass through the magnet.

Iron oxide beads may also be of a particular size, i.e. nanoparticles, such that the beads are super-paramagnetic, with advantages that the beads are not magnetized when there is no strong applied field, while on the other hand developing a very large magnetic moment when subjected to a magnetic field. The lack of a permanent magnetic moment can keep the beads from aggregating in the absence of an applied magnetic field.

The effect on the surrounding medium of beads with smaller magnetic moments can be different from the effect of beads with larger magnetic moments because the size of the volume of surrounding fluid affected by the bead is roughly proportional to the magnetic moment of the beads. This can be used to facilitate differentiation of targets to which beads preferentially attach. To achieve differences in magnetic moment of bead labels, beads containing different densities of magnetic material, beads of different sizes, beads containing different materials, or any combination of these or other factors may be employed. Differentiation may also be achieved by variations in the multiplicity of the labeling, for example, with larger targets carrying more beads on their surface.

In an example of one embodiment, two species of bacteria are present in a fluid, and each are specifically labeled with beads with the associated antibody targeting the specific species of bacteria. The amount of iron oxide in the beads of the label for, in one example, bacteria 2 (B2) is larger than that of the label for bacteria 1 (B1). Including the effect of the average binding density of the bead labels to the target bacteria, it is possible to differentiate the signals from the two species of bacteria based on the differences in the net magnetic moment, and therefore the amount of fluid medium the targeted bacteria affects as it flows through the detection coil. The detection events are manifested in a reduction in the signal from the medium, with the target with larger net magnetic moment producing a larger decrease in signal.

It may be advantageous to provide additional labeling to the sample, for example to increase the signal associated with a detection event, wherein the initial label bead itself is subsequently labeled by additional beads. These secondary beads may be appropriate for creating additional signal or entity differentiation. For example, secondary beads containing a larger fraction of magnetic material may be constructed to bind to primary beads which recognize a particular entity, while other secondary beads, containing a smaller fraction of magnetic material may be constructed to bind to primary beads which recognize a separate entity. Differentiation of one labeled entity from the other would be accomplished by an analysis of the resulting signal from the medium. Secondary beads could be used to alter the signal in some other way, for example adding ferromagnetic secondary beads to the initial beads for a particular bacterial species, and paramagnetic secondary beads to the initial beads for another bacterial species, and in this way differentiate between two or more bacterial species.

The methods may be used for rare entity detection or for entity concentration measurement device. In rare entity mode, the detector will generally have only one target entity in its sensitive volume at any one time. In this mode, the goal of the device is to find the rare target in a relatively large volume of fluid that is flowing through the detector volume. In concentration mode, the detector will have many targets in the sensitive volume and the methods can be used to characterize the concentration in relative or absolute terms.

Signal differentiation may also be achieved through control of the magnetic moment of the bead that is attached to a particular target. This may be achieved through control of the amount of magnetic material in a bead, the size of beads at a given concentration, the type of magnetic material used to produce different magnetic moments, the number of beads attached, and so on. Thus it is possible to provide, for example, multiply labeled species or strains of pathogens and have them be uniquely identified by characteristics of the NMR signal, such as amplitude.

Differentiation between targets may be achieved via measurements of secondary effects of the labels on the detected signal. For example, the detection of the presence of a target may be achieved by making one kind of measurement, for example T₂*, while the differentiation between different targets so detected may be achieved via the measurement of a second NMR property, for example T₁. The differentiation may be enhanced through the use of more than one kind of bead that share the same (or nearly the same) values of some detection properties while differing in other properties. These different beads may label distinct targets, or some combination of beads might label each target, with the combination being distinct from one target to the other.

In addition to a magnetic label, further entity differentiation can be achieved through the attachment of other material to the target, such as fluorescent, optical-absorption, or acoustic labels. An example of an acoustic label is a structure with a characteristic ultrasonic signature. Fluorescent labels include fluorophores (fluorescein, rhodamine) and quantum dots. This additional labeling may be provided to, for example, do sample detection and identification either in conjunction with or as a separate step, before or after the detection according to the methods of the invention. For example the detection event can trigger the isolation, or sequestration of the detected bacteria into a separate fluid path, wherein it could be further interrogated, for example optically using fluorescence or absorption. The additional labels may be attached before or after the detection step, or may be integrated into a single object as a “multi-modal” label.

The matrix fluid in which labeled bacteria are processed may be changed or modified to enhance signal. Useful changes may be made to the hydrogen density, viscosity, or other chemical or physical properties of the fluid. The changes can be achieved by replacement of one fluid by another, by the addition of solid or fluid components to the matrix fluid, by changing the temperature or pressure of the fluid, etc. These changes may affect the T₁, T₂, or T₂* of the fluid in a beneficial way, for example, by yielding higher detection signals and allowing faster processing. The T₁ of the fluid may be reduced through the introduction of Magnevist or any other T₁ contrast agent. Shorter T₁s are beneficial in that the detection measurement can be performed more rapidly, and repeated at higher rate.

The labeling of individual target entities can rely on well-known, antibody-based techniques. Antibodies are protein molecules which recognize particular chemical sites, called epitopes, on other molecules. Antibodies can be attached, either chemically, or biochemically, to the surfaces of primary or secondary magnetic beads. A biochemical example would be a bead coated with steptavidin, a protein which binds very tightly to biotin. Then, a biotinylated antibody for a particular entity will bind to a streptavidin-coated bead. A solution of antibody-labeled beads is then mixed with the fluid material in which the entity (such as a pathogen) resides, for example bacteria in blood. Based on the type of antibody coating of the bead, a bead, or many beads, will attach to the target bacteria. The blood containing the labeled bacteria then flows through the detection coil, allowing the presence of the labeled bacteria to be ascertained.

Alternatively, the target entities may be trapped on a solid phase, such as in an affinity column or other column known from chromatography. Once attached to the solid and immobilized, the solution of label beads with attached antibodies may be introduced so that all of the attached targets are labeled with beads. The excess beads that do not label any target may then be washed out of the column. The targets, with their labels attached, may then be eluted from the column and this elutant can then be processed by the NMR detector.

If many beads attach to a single bacterium the effect of the labeled bacterium on the signal from the medium can be easily observed against the background signal the medium in the presence of isolated single beads. Alternatively, when only a single bead is attached to a bacterium, the unbound beads are preferably removed. The removal of the excess beads may be accomplished by any suitable means. In one example, antibody-beads are incubated with the clinical sample; unattached antibody-beads are then washed through a one-way valve, such as a silicon with a pore size on nm scale (ie: too small for any target pathogens). A second valve would then open and a second wash would send only bead-antibody-complexes and blood components into the detector. Alternatively, the removal of the excess beads may be accomplished by a filter column.

The fluid flow may be stopped during the detection, or the flow may be continuous. For example, the method may comprise detecting the presence of a target entity during fluid flow, followed by a second detection, with fluid flow or with fluid flow stopped, to determine the identity of the detected target entity. Either a single detector coil could be used, with control of the flow (including reversing the flow to bring the target back into the coil), or a secondary coil (placed downstream from the initial detector coil, or in a branch into which the target is steered) could be used. The entities to be detected may pass through the detector and into an sequestration chamber without being substantially modified. Living organisms or cells retain viability. The output fluid is available for further testing or repeat testing in the device, in a similar device optimized for a different measurement, or any other device or process. Sequestered target entities can be sequestered into a very small volume to enable the rapid location of the targets on a microscope slide or the rapid processing of only the small volume in subsequent processes or devices. The collected, concentrated targets may be further analyzed in the detector, either in the coil used to detect them in the first place, or in a separate detection circuit or method.

The magnetic field may be produced by a permanent magnet, such as the permanent magnets described as part of the detector aspect of the present invention, for example. Any of the magnetic gradient generators that may be used in the detector aspect of the invention may also be used to apply a magnetic gradient to a magnetic field according to the methods of this aspect. Any of the microcoils, conduits, and combinations thereof disclosed above may also be used according to the methods of the invention. Further multiplexing of the methods can be achieved by use of conduits comprising multiple branches, which can be coupled with the use of multiple microcoils to provide a variety of detection zones, and further coupled with microfluidics to permit, for example, (i) selective flow of a fluid sample of interest to multiple detection zones for separate detection assays (i.e.: different fluid flows; different field strengths; different magnetic gradients; combinations thereof; etc.); and (ii) selective flow of multiple fluid samples of interest to separate detection zones for sample multiplexing. Other variations will be apparent to those of skill in the art based on the teachings herein.

Any method of causing the fluid to flow may be used. For example, any of the fluidic drives disclosed above may be used to impart a flow on the fluid. The flow rate used can be any rate desirable for a given application. As used herein, “flow rate” refers to the amount of fluid that moves through the sensitive volume of the detector over time. In one embodiment, the flow rate of the fluid may be between 0.01 microliters per minute and 2.0 microliters per minute. In various other embodiments, the flow rate can be between 0.01-500, 0.01-450, 0.01-400, 0.01-350, 0.01-300, 0.01-250, 0.01-200, 0.01-150, 0.01-100, 0.01-50, 0.01-10, 0.01-8, 0.01-6, 0.01-4, 0.01-3, 0.01-2, 0.01-1.75, 0.01-1.50, 0.01-1.25, 0.01-1.0, 0.01-0.9, 0.01-0.8, 0.01-0.7, 0.01-0.6, 0.01-0.5, 0.5-2.5, 0.5-2.25, 0.5-2.0, 0.5-1.9, 0.5-1.8, 0.5-1.7, 0.5-1.6, 0.5-1.5, 0.5-1.4, 0.5-1.3, 0.5-1.2, 0.5-1.0, 150-250, 175-225, 180-220, 185-215, 190-210, 195-205, 198-202 and 199-201 microliters per minute depending on the properties of the fluid and the particular experiment that uses the methods of the present invention. Lower flow rates and even static fluids may also be used. Any flow rate that permits the detection of a magnetic resonance within the fluid may be used. The flow rates outside the sensitive volume of the detector may also vary. For example, fluid that is held in sequestration chamber or held behind a valve may be static. For fluid flowing through an affinity column, or through a portion of the conduit that distributes fluid samples to other conduit branches, the flow rates may be higher. Further, the flow rate through the sensitive volume of the detector may be varied. For example, a valve placed before the sensitive volume of the detector may be used to increase or decrease the flow rate during the course of a detection experiment. In an example method, a detection experiment is primarily conducted at 2 microliters per minute. However, if a signal received from the microcoil indicates that an entity might be present in the fluid, a valve may be activated to slow the flow rate through the sensitive volume of the detector to 1.0 microliters per minute. In another example method, a detection experiment may commence at flow rate of 0.5 microliters per minute. If, after a predetermined period of time no entities have been detected, a valve may be activated to increase the flow rate through the sensitive volume of the detector to complete the detection experiment more quickly.

When a flowing fluid enters the magnetic field, the magnetic field causes some of the nuclei in the fluid to align with the field. The magnetic gradient causes the nuclei within the fluid to resonate at different frequencies depending on their location relative to the magnetic field and the magnetic field gradient. By altering the frequencies at which the nuclei in the fluid resonate, the magnetic gradient establishes the spatial resolution of the detector, which permits the detection of an entity within an identifiable section of the microcoil. In an example implementation of the methods of the invention, the conduit is positioned such that a long axis of the conduit is parallel with the direction of the gradient. However, the conduit can be disposed elsewhere within the field of the magnetic gradient generator provided there is sufficient gradient component along the conduit to spatially resolve magnetic resonance events along the conduit.

The methods of the invention comprise energizing the microcoil at a frequency that permits detection of a magnetic resonance within the fluid. The microcoil is used to transmit a pulsed electromagnetic signal at a selected resonant frequency towards the fluid in the conduit. The frequency of the transmitted signal is selected based on the properties of the particular nuclei that are being examined in the detection experiment and the strength of the magnetic field. The microcoil is also used to detect the energy that is absorbed or released by the nuclei in the magnetic field in response to the transmission of the resonant frequency signal. This energy induces an electrical current in the microcoil that corresponds with the energy absorbed or released by the nuclei in the flowing fluid. The presence of an entity within the fluid causes a change in energy that can be detected by the microcoil.

The methods also comprise processing a signal received from the microcoil to detect an entity in the fluid. The combination of the magnetic gradient and the magnetic field causes the field strength to vary along the length of the conduit, which in turn causes the nuclei within the fluid to resonate at different frequencies depending on the location of the fluid, permitting identification of numerous contiguous signal producing volume elements along the microcoil. Consequently, the microcoil receives signals from the fluid at a plurality of frequencies, each corresponding to the location of the fluid. By correlating the frequency and magnitude components of the signals received by the microcoil to the corresponding locations within the conduit, measurements identifying the magnetic resonant behavior of the fluid throughout the length of a portion of the conduit can be obtained.

These measurements can be converted into graphical representations of the movement of an entity though the fluid. The construction of a graphical representation from the signal received from the microcoil can be accomplished using a variety of techniques, including but not limited to a Fourier transformation. In an example implementation of the method, a Fast Fourier Transform technique is used. Baseline correction techniques and phase adjustments may also be used to augment the signal processing. The signal processor may display the signal received from the microcoil in processed or unprocessed form on a user interface such as a monitor or screen.

Other data manipulations may also be particularly useful for reducing the susceptibility to false positive and false negative detections. If the data is acquired in a manner that allows subsets of the signal detected by the microcoil to be assigned to different positions within the conduit, a device implementing the method can become self-calibrating. Further, the determination that an entity is present or absent in a portion of the conduit may be based on detecting a change in a magnitude component relative to a plurality of other magnitude components. Comparing relative magnitudes may reduce the probability that a global increase or decrease in a processed signal that is unrelated to the presence or absence of an entity in the fluid would trigger a detection event.

The processing of a signal may also include comparing data from successive signal acquisitions. In implementations that impose a unidirectional flow on the fluid, an entity in the fluid may pass through the detector from one end of the conduit to the other. By comparing successive data acquisitions, the passage of an entity through the conduit may be tracked. Further, in implementations that compare successive data acquisitions, data analysis techniques such as correlation analyses may be used to reject false detections due to electrical noise or other random fluctuations, because it is unlikely that electrical noise or other random fluctuations would mimic the appearance of an entity moving through a fluid in multiple data acquisitions.

The processing of a signal may also include accumulating signal peaks of a graphical representation of the signal received from a microcoil. Accumulating signal peaks may allow multiple scans to be correlated and combined to show the movement of an entity through the fluid. A characteristic velocity of a signal peak that is related to a radial position in a conduit of an entity can be used to accumulate signal peaks across successive scans.

Motion correction methods may also be utilized to further enhance the accuracy of the data acquired. In embodiments where the fluid flow is relatively slow or static, spin-echo or gradient-recalled echo images may be formed. In embodiments using pulsed field gradients, the signal-to-noise ratio and accuracy of the images may be further improved. Multi-dimensional imaging may also be implemented with embodiments that use slow or static flows. Embodiments that implement echo-based techniques may allow a plurality of effects of a labeled entity's presence in a fluid to be measured and imaged.

In embodiments with multiple branches and multiple microcoils, various methods may be used to identify the magnetic resonance behaviors within a given microcoil. For example, the microcoils may be angled with respect to the magnetic gradient such that each spatial element of each microcoil resonates at a different range of frequencies. In another example, electrical switching could be used to selectively monitor a microcoil for a period of time. In another example, each microcoil may be coupled to a dedicated signal processor.

The methods of the invention may further comprise electrically coupling the microcoil to a tuning circuit, wherein the tuning circuit comprises a tuning coil having an inductance at least two times the inductance of the microcoil and a capacitor coupled to the tuning coil to form a resonant circuit. Any of the tuning circuits disclosed above may be used as the tuning circuit.

Further, any of the methods of this aspect of the present invention may be implemented by a computer program for use with a detector, such as those disclosed herein. The computer program may be implemented in software or in hardware, or a combination of both hardware and software.

In a further aspect, the present invention provides computer readable storage media, for automatically carrying out the methods of the invention on a detector, such as those disclosed herein. As used herein the term “computer readable medium” includes magnetic disks, optical disks, organic memory, and any other volatile (e.g., Random Access Memory (“RAM”)) or non-volatile (e.g., Read-Only Memory (“ROM”)) mass storage system readable by the CPU. The computer readable medium includes cooperating or interconnected computer readable medium, which exist exclusively on the processing system or be distributed among multiple interconnected processing systems that may be local or remote to the processing system.

### Examples

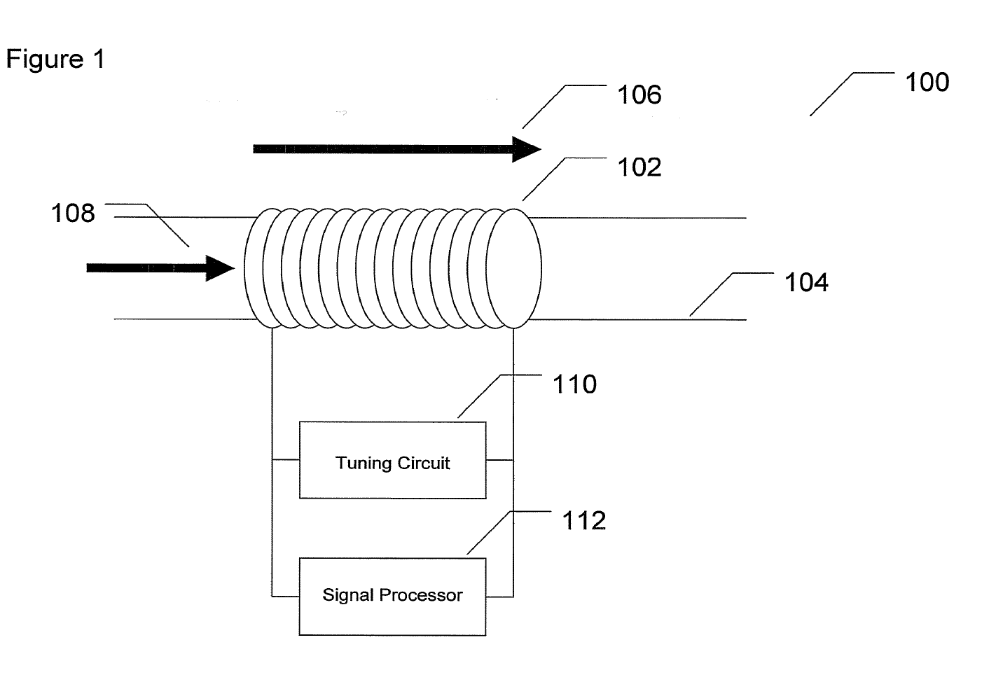

Referring now to the figures, FIG. 1 depicts a portion of an exemplary microcoil MRI detector 100. A microcoil 102 is solenoidally shaped and wrapped around a conduit 104. The portion the conduit 104 that is within the microcoil 102 is the sensitive volume of the detector 100. The axis of conduit 104 is aligned with a magnetic gradient 106. In a detection experiment, a fluid flowing in direction 108 passes through the conduit 104 and the microcoil 102. The microcoil 102 is electrically coupled to both a tuning circuit 110, and a signal processor 112.

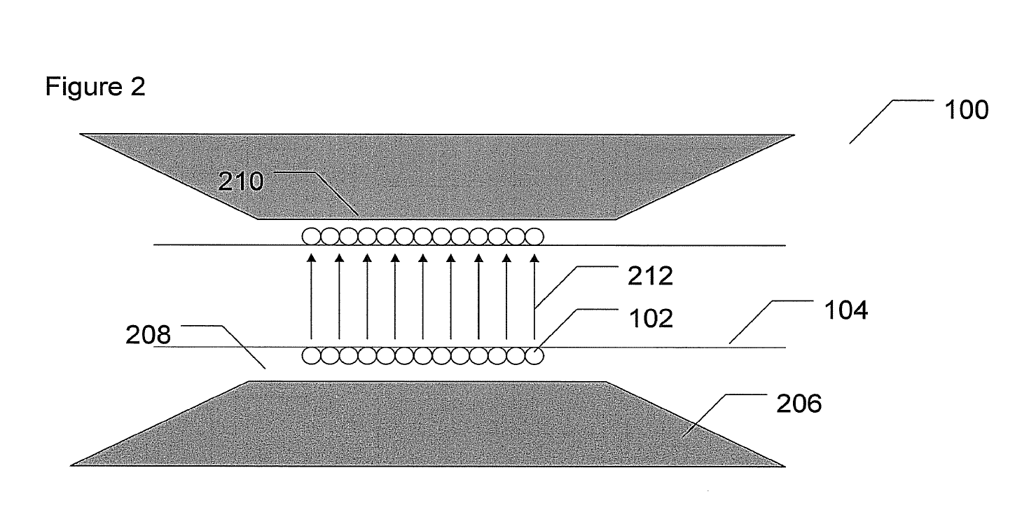

FIG. 2 depicts a cross-sectional view of a portion of an exemplary MRI detector 100. The microcoil 102 is wrapped around the conduit 104 and disposed in a gap in a magnet 206. Magnet pole faces 208 and 210 possess opposite polarity, and a uniform magnetic field 212 is established across the gap in magnet 206.

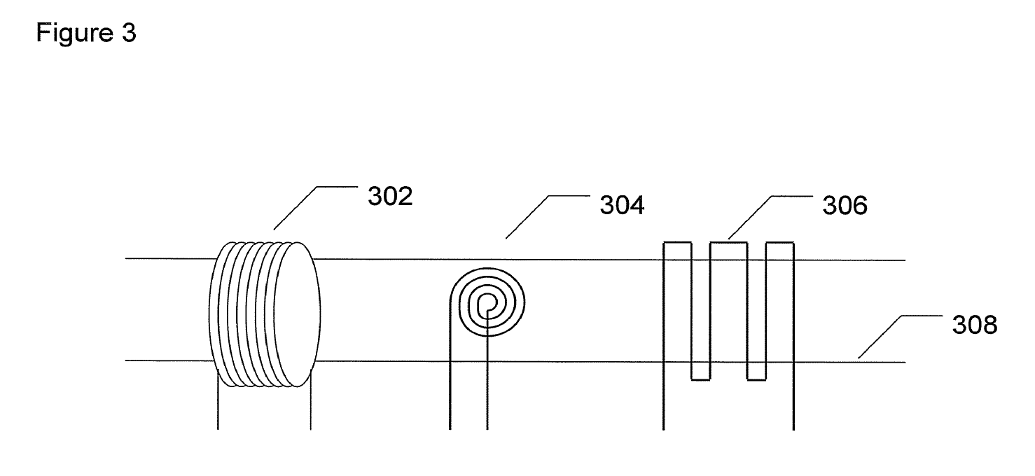

FIG. 3 depicts three different example microcoil constructions 302, 304, and 306. The first microcoil 302 is a solenoidal coil wrapped around a conduit 308. The second microcoil 304 is a flat coil, positioned adjacent to the conduit and oriented to place the axis of the second microcoil 304 perpendicularly to the axis of conduit 308. The third microcoil 306 is a meanderline coil place adjacent to the conduit 308.

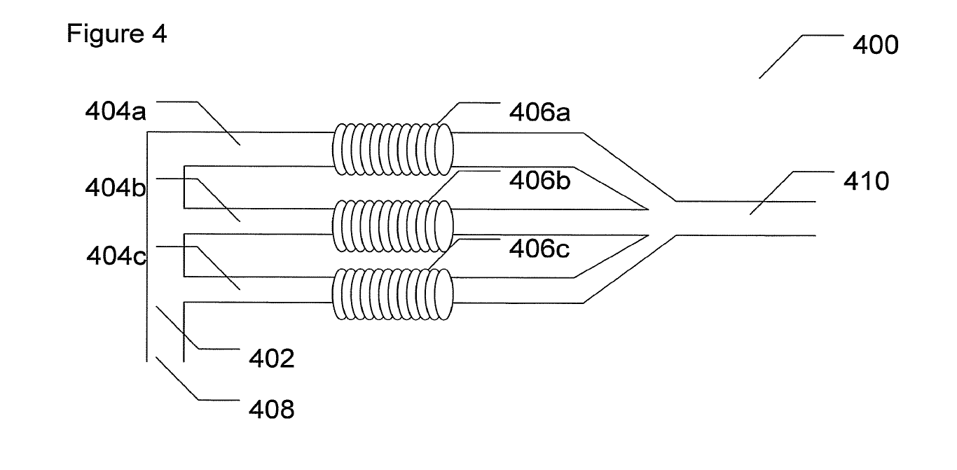

FIG. 4 depicts a portion of an example detector 400 wherein a conduit 402 contains three conduit branches 404a-404c. Microcoils 406a-406c are solenoidal in shape and are wrapped around conduit branches 404a-404c. A fluid can flow into the conduit at a fluid input 408, and flow out of the conduit at a fluid output 410. In example detector 400, each of conduit branches 404a-404c and microcoils 406a-406c may be independent. For example, each of microcoils 406a-406c may be energized at a different frequency or range of frequencies, which may permit detection of different entities in each of conduit branches 406a-406c. However, microcoils 406a-406c may each be used in identical detection experiments, which may further reduce the susceptibility of the detector to false positive or false negative detections, by allowing for the flow rate through the sensitive volumes of the conduits to be reduced.

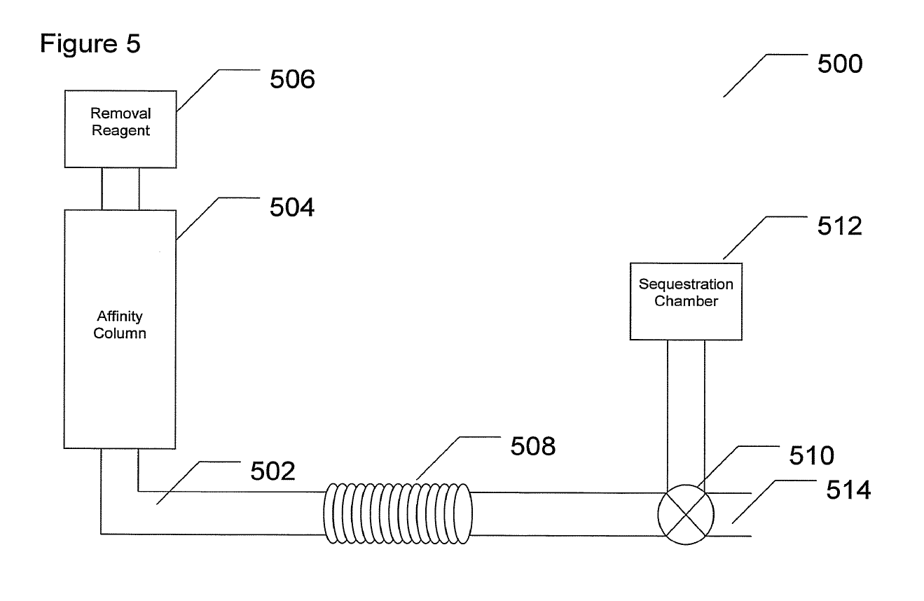

FIG. 5 depicts a portion of example detector 500 comprising additional fluidic components fluidically coupled to a conduit 502. An affinity column 504 may be used to trap and hold pathogens or other entities until a detection experiment can be conducted. During a detection experiment, a fluid containing a removal reagent 506 may flow past the affinity column 504, and cause pathogens or other entities to enter the fluid. The fluid can then flow through the section of the conduit 502 that is wrapped by a microcoil 508. If an entity is detected by microcoil 508, a valve 510 can be activated to divert the fluid into a sequestration chamber 512 for storage or further analysis. If no entities are detected, the valve 510 may allow the fluid to exit the conduit through fluid output 514.

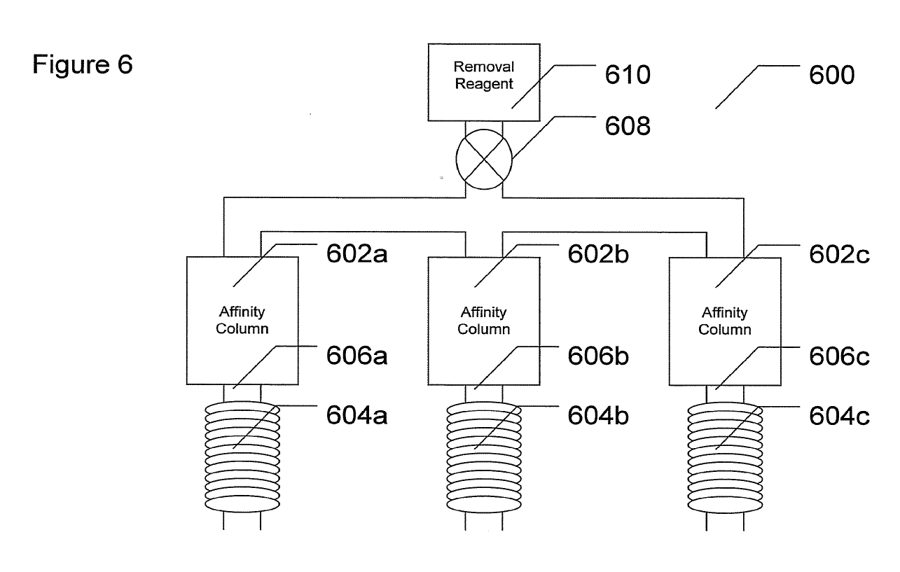

FIG. 6 depicts a portion of example detector 600 comprising multiple affinity columns 602a-602c. At the output end of each of the affinity columns, solenoidal microcoils 604a-604c are wrapped around conduits 606a-606c. A valve 608 controls the flow of a removal reagent 610 past the affinity columns 602a-602c. The use of multiple affinity columns 602a-602c may permit additional differentiation and increase the throughput of the detector. For example, a detection method may provide ten levels of discernable signal differentiation and use ten specific beads in each of the affinity columns 602a-602c. By processing each affinity column 602a-602c separately, the flow through the microcoils 604a-604c is multiplexed, permitting thirty distinct potential identifications using only ten bead characteristic levels. Further, since three affinity columns 602a-602c are used, a sample can be divided into three portions, permitting the sample to be analyzed three times more quickly than with a single column.

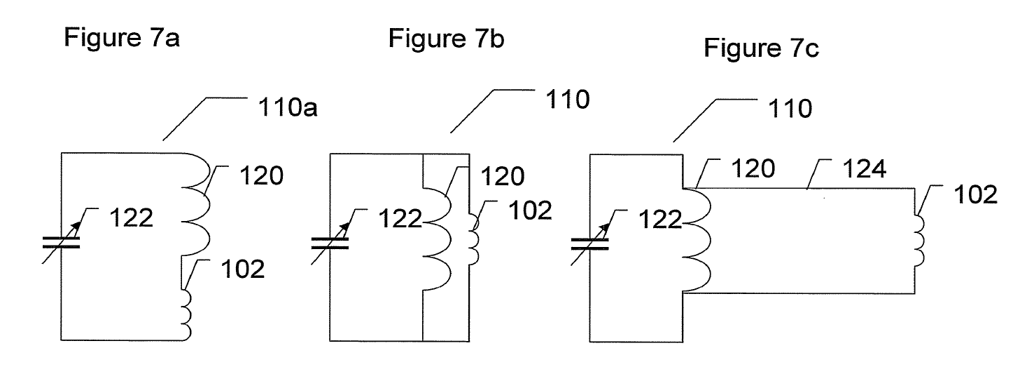

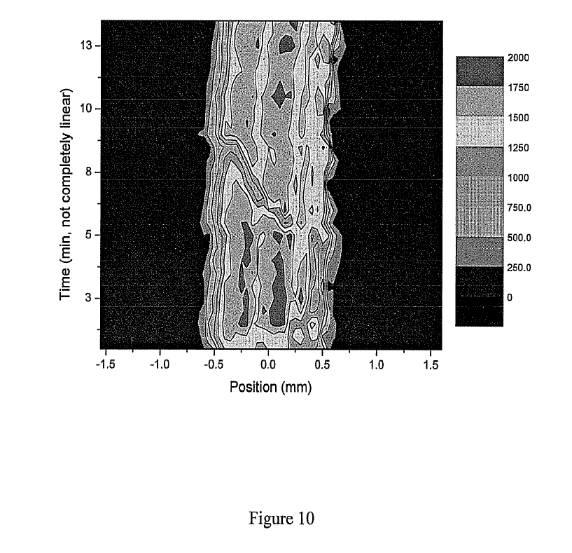

FIGS. 7a-7c depict three example schematic arrangements of the tuning circuit 110 and the microcoil 102. In FIG. 10a, the tuning coil 120 and the microcoil 102 are connected in series, and a resonant circuit is formed with a tuning capacitor 122. In FIG. 10b, the tuning coil 120 and the microcoil 102 are connected in parallel. In FIG. 10c, the tuning coil 120 and the microcoil 102 are again connected in parallel, but the microcoil 102 is remotely located from the tuning circuit 110 via a transmission line 124. In an example detector, the transmission line possesses a length that is an odd multiple (i.e. 1×, 3×, 5×) of one-fourth of the wavelength of the alternating current induced in the microcoil during resonance.

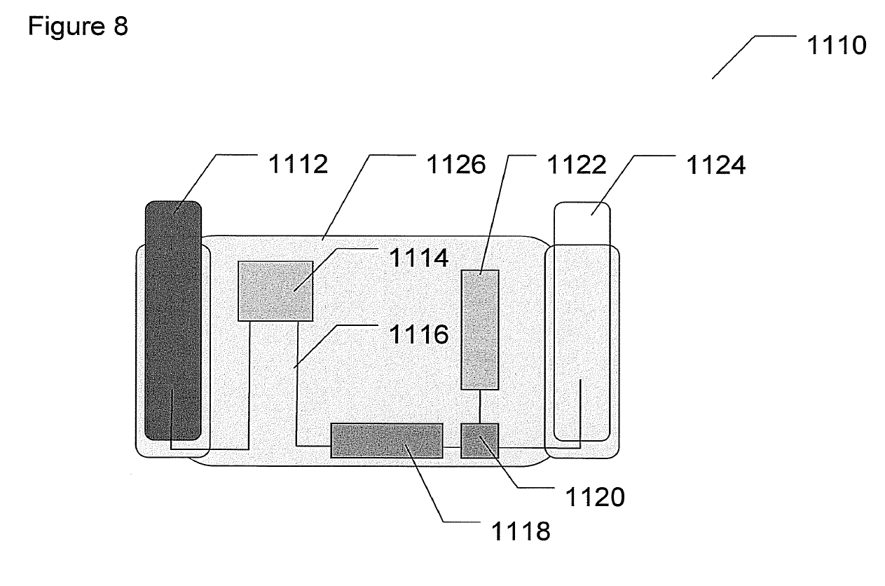

FIG. 8 depicts an example module 1100 wherein a fluid is contained in a sample chamber 1112. The sample chamber 1112 is fluidically coupled to a bead chamber 1114 that contains beads that can be affixed to a target entity in the fluid. A conduit 1116 is fluidically coupled to the bead chamber 1114, passes through a microcoil 1118, and is fluidically coupled to a valve 1120 after passing through the microcoil 1118. The valve 1120 is fluidically coupled to a sequestration chamber 1122 and a exit reservoir 1124. If during a detection experiment the microcoil 1118 detects a magnetic resonance in the fluid that indicates the presence of a target entity, the valve 1120 can be activated to divert the fluid into the sequestration chamber 1122. If no target entity is detected, the valve 1120 can be activated to direct the fluid into the exit reservoir 1124. All of components of module 1100 are mechanically coupled to a substrate 1126, which provides structure support and maintains the relative position of the components on the module 1100.

In an exemplary embodiment, a microcoil with an inner diameter of 170 microns and a length of approximately 1.1 mm is wound around a conduit. The conduit and microcoil are disposed in a magnetic field with a strength of about 1 Tesla, generated by a permanent magnet, and a magnetic gradient of 0.07 G/mm is applied along the long axis of the microcoil. As fluid is passed through the conduit, the data acquisition techniques disclosed above are applied to detect the presence of a labeled entity in the fluid.

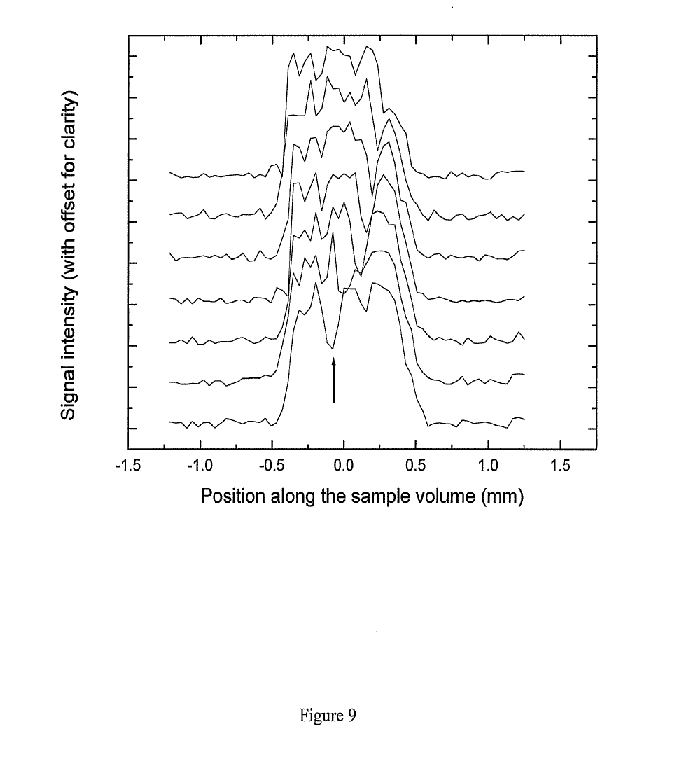

The example device was used in a successful implementation of the method. A fluid consisting of Magnevist doped water (T1˜430 ms) and dilute magnetic beads (5 micron Bangs beads), was disposed in the conduit, and by following a method of the present invention, a bead was positively identified. FIG. 9 contains a time series of images, offset for clarity, in which the bead appears as a dip in the profile as indicated by the arrow.

FIG. 10 depicts the full time course of a detection experiment as a contour plot. In FIG. 2, the positively identified bead appears as a linear feature moving diagonally up and to the left across the centrally located band. The centrally located band depicts the location of the sample volume.

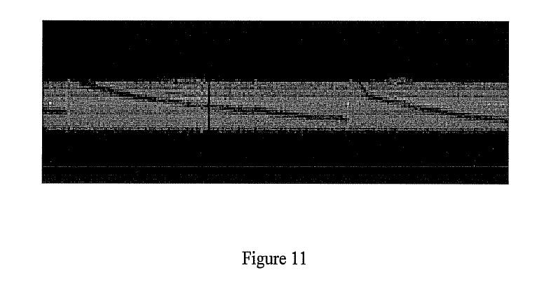

FIG. 11 depicts a data set from a similar detection experiment using the example device and a method of the present invention. A positively detected bead is visible as dark bands trending to the lower right within the light band.

Various arrangements and embodiments in accordance with the present invention have been described herein. All embodiments of each aspect of the invention can be used with embodiments of other aspects of the invention. It will be appreciated, however, that those skilled in the art will understand that changes and modifications may be made to these arrangements and embodiments, as well as combinations of the various embodiments without departing from the true scope and spirit of the present invention, which is defined by the following claims.

1. A detector comprising:
a permanent magnet possessing a field strength, wherein the field strength is less than or equal to 4 Tesla;
a magnetic gradient generator capable of applying a magnetic gradient to a magnetic field generated by the permanent magnet; and
a microcoil disposed proximate to the magnetic field generated by the permanent magnet wherein the microcoil possesses an inner diameter of between 25 microns and 550 microns.

2. The detector of claim 2 further comprising a conduit guide capable of receiving a conduit for receiving a fluid, and wherein the conduit guide is capable of disposing the conduit proximate to the microcoil and proximate to the magnetic field generated by the permanent magnet, and wherein the microcoil is capable of being energized at a frequency corresponding to the magnetic field strength of the permanent magnet that permits detection of a magnetic resonance within a volume of fluid within the conduit.

3. The detector of claim 1 further comprising a conduit disposed proximate to the microcoil.

4. The detector of claim 2 further comprising a conduit disposed on the conduit guide.

5. The detector of claim 4 wherein the conduit and the microcoil are both disposed on a module; and the conduit guide is capable of receiving the module.

6. The detector of any one of claims 2-5 further comprising a signal processor electrically coupled to the microcoil and capable of identifying a plurality of frequency components and a plurality of magnitude components within the signal received from the microcoil, and correlating the plurality of magnitude components and plurality of frequency components to a presence or absence of an entity in a volume of fluid at a plurality of locations along an axial length of the conduit.

7. The detector of any one of claims 2-6 further comprising a fluidic drive capable of being fluidically coupled to the conduit.

8. The detector of any one of claims 1-7 further comprising a tuning circuit electrically coupled to the microcoil, wherein the tuning circuit comprises:
a tuning coil capable of having an inductance at least two times larger than the inductance of the microcoil, and
a capacitor coupled to the tuning coil to form a resonant circuit.

9. The detector of any one of claims 2-8 wherein the conduit comprises a plurality of branches capable of receiving a volume of fluid.

10. The detector of claim 9 wherein the plurality of branches are disposed proximate to a plurality of microcoils, wherein each microcoil within the plurality of microcoils possesses an inner diameter between 25 microns and 550 microns.

11. A detector comprising:
a permanent magnet possessing a field strength, wherein the field strength is less than or equal to 4 Tesla
a magnetic gradient generator capable of applying a magnetic gradient to a magnetic field generated by the permanent magnet; and
a conduit guide capable of receiving (i) a conduit for receiving a fluid, and (ii) a microcoil capable of being energized at a frequency that permits detection of a magnetic resonance within a volume of fluid within the conduit;
wherein the conduit guide is capable of disposing the microcoil proximate to (i) the magnetic field generated by the permanent magnet and (ii) the magnetic gradient, and wherein the conduit guide is capable of disposing the conduit proximate to the microcoil.

12. The detector of claim 11, further comprising:
a tuning circuit capable of being electrically coupled to the microcoil, wherein the tuning circuit comprises a tuning coil coupled to a capacitor to form a resonant circuit, and wherein the tuning coil possesses an inductance of at least 2 nH.

13. The detector of claim 12 further comprising a microcoil disposed on the conduit guide, wherein the microcoil is (i) disposed proximate to the magnetic field generated by the permanent magnet, (ii) capable of being energized at a frequency that permits detection of a magnetic resonance within a volume of fluid, and (iii) electrically coupled to the tuning circuit.

14. The detector of claim 13, wherein the microcoil possesses an inner diameter between 25 microns and 550 microns;

15. The detector of any one of claims 12-14 further comprising a conduit disposed on the conduit guide, wherein the conduit is (i) disposed proximate to the microcoil and (ii) capable of receiving a volume of fluid.

16. The detector of claim 15 further comprising a fluidic drive fluidically coupled to the conduit.

17. The detector of any one of claims 15-16 wherein the conduit and the microcoil are both disposed on a module; and wherein the module is disposed on the conduit guide.

18. The detector of any one of claims 15-17 wherein the conduit comprises a plurality of branches capable of receiving a volume of fluid.

19. The detector of claim 18 wherein the plurality of branches are disposed proximate to a plurality of microcoils, wherein each microcoil within the plurality of microcoils possesses an inner diameter between 25 microns and 550 microns.

20. The detector of any one of claims 11-19 further comprising a signal processor capable of being electrically coupled to the microcoil and capable of identifying a plurality of frequency components and a plurality of magnitude components within the signal received from the microcoil, and correlating the plurality of magnitude components and plurality of frequency components to a presence or absence of an entity in the volume of fluid at a plurality of locations along an axial length of the microcoil.

21. A method for detecting a labeled entity in a flowing fluid, comprising:
applying a magnetic gradient to a magnetic field, wherein a conduit containing a flowing fluid is disposed in the magnetic field, and within the magnetic gradient, and wherein a microcoil is disposed proximate to the conduit;
energizing the microcoil at a frequency that permits detection of a magnetic resonance within the flowing fluid; and
processing a signal received from the microcoil to detect a labeled entity in the flowing fluid, wherein the processing comprises:
identifying a plurality of frequency components and a plurality of magnitude components within the signal received from the microcoil, and correlating the plurality of magnitude components and plurality of frequency components to a presence or absence of a labeled entity in the flowing fluid at a plurality of locations along an axial length of the microcoil.

22. The method of claim 21, wherein the processing comprises processing a plurality of signals received from the microcoil over time, wherein the processing comprises identifying a plurality of frequency components and a plurality of magnitude components within each signal received from the microcoil, and correlating the plurality of magnitude components and plurality of frequency components within each signal to a presence or absence of a labeled entity in the flowing fluid at a plurality of locations along an axial length of the microcoil.

23. The method of claim 21 or 22 wherein the flowing fluid in the conduit flows between 0.01 microliters per minute and 500 microliters per minute.

24. The method of any one of claims 21-23 wherein energizing the microcoil at a frequency that permits detection of a magnetic resonance within the fluid comprises electrically coupling the microcoil to a tuning circuit, wherein the tuning circuit comprises a tuning coil having an inductance at least two times the inductance of the microcoil and a capacitor coupled to the tuning coil to form a resonant circuit.

25. The method of any one of claims 21-24, wherein the processing comprises generating an image depicting the plurality of frequency components and the plurality of magnitude components.

26. The method of any one of claims 21-25 wherein the processing further comprises performing a Fourier transformation on the signal received from the microcoil.

27. The method of claim 26 wherein performing a Fourier transformation comprises using a Fast Fourier Transform technique.

28. The method of claim 26 or 27 wherein performing a Fourier transformation further comprises using baseline correction techniques and phase adjustment techniques.

29. The method of any one of claims 21-28 wherein the processing further comprises comparing a first subset of the plurality of magnitude components to a second subset of the plurality of magnitude components.

30. A computer program implementing the method of any one of claims 21-29.

31. A module comprising:
a microcoil, wherein the microcoil possesses an inner diameter between 25 microns and 550 microns;
a conduit disposed proximate to the microcoil; and
a connector for connecting the module to a detector.

32. The module of claim 30, further comprising electrical contacts capable of establishing an electrical connection between the module and an electrical component within the detector.

33. The module of claim 31 or 32 further comprising a fluidic drive fluidically coupled to the conduit.

34. The module of any one of claims 31-33, further comprising a valve fluidically coupled to the conduit on the module.

35. The module of any one of claims 31-34 further comprising a sequestration chamber fluidically coupled to the conduit.

36. The module of any one of claims 31-35, further comprising an affinity column fluidically coupled to the conduit.
